(19) United States
(12) Patent Application Publication
(10) Pub. No.: US 2014/0353501 A1
(43) Pub. Date: Dec. 4, 2014

(54) NIGHT VISION ATTACHMENT FOR SMART CAMERA

(71) Applicant: OPTIKOS CORPORATION, Wakefield, MA (US)

(72) Inventors: STEPHEN D. FANTONE, Lynnfield, MA (US); Bradley S Faecher, Sudbury, MA (US); Will Russin, III, Boston, MA (US); Daniel Orband, Boxford, MA (US)

(21) Appl. No.: 13/903,374

(22) Filed: May 28, 2013

(51) Int. Cl. H01L 27/146

(52) U.S. Cl. CPC H01L 27/14649
USPC 250/330; 250/208.1

(57) ABSTRACT

A night vision attachment for a SmartPhone by which the camera of the SmartPhone is enabled to view or take digital photos of objects under very low light ambient light levels. The night vision attachment comprises a housing for receiving and locating components of the attachment and has portions adapted to mate with a wall of the camera through which the phone camera lens images object space. Located in the attachment housing are an image detector sensitive to infrared (IR), an objective lens for forming images on the image detector whereby the image detector operates to generate image output signals representative of detected images, a display arranged to receive the image output signals from the image detector and to generate a visible image; and an eyepiece for viewing images formed on the display and permitting the camera of the phone to focus on the display images when the attachment is mated to a phone. IR LEDs are used to illuminate scenes. Snap fit connectors releasably hold the attachment in mating contact with the phone so that the camera of the phone is optically aligned with the axis of the eyepiece to permit the camera to view images on the display via the eyepiece.

### FIELD OF THE INVENTION

This invention generally relates to night vision apparatus and more specifically to an attachment for a cellular or Smartphone for converting its camera for low light level digital imaging.

### BACKGROUND OF THE INVENTION

Smartphones are handheld electronic devices built on a mobile operating system to provide more advanced computing capability and connectivity than a conventional cellular telephone. The first smartphones combined the functions of a personal digital assistant (FDA) with a mobile phone. Later models added the functionality of portable media players, low-end compact digital cameras, pocket video cameras, and GPS navigation units to form one multi-use device. Many modern Smartphones also include high-resolution touch screens and web browsers that can display standard web pages as well as mobile-optimized sites. High-speed data access is provided by Wi-Fi and mobile broadband. In recent years, the rapid development of mobile app markets and of mobile commerce have been drivers of Smartphone adoption.

The mobile operating systems (OS) used by modern smartphones include Google's Android, Apple's iOS, Nokia's Symbian, RIM's BlackBerry OS, Samsung's Bada, Microsoft's Windows Phone, Hewlett-Packard's webOS, and embedded Linux distributions such as Maemo and MeeGo. Such operating systems can be installed on many different phone models, and typically each device can receive multiple OS software updates over its lifetime.

The past several decades has also seen the development of steadily improving lens designs that have evolved to the point where they have become suitable for integration into cellular phones and, more recently, Smartphones. Indeed, the bulk of digital images created today are taken with cellular phones equipped with digital cameras, thus making point and shoot cameras an endangered species. Even so, such phones do have limitations. For example, it is difficult to snap good close-ups, distant shots, or night vision shots or videos where lighting is so poor the camera is unable to cope.

While attachments have been provided to improve close-up and distant shots, none exists for permitting a user to take night vision shots or videos or display screen images visible to a user under poor ambient lighting.

Accordingly, it is a primary object of the present invention to provide an attachment for a Smartphone that will enable a user to take night vision digital photos and videos under poor lighting conditions.

It is another object of the present invention to provide an attachment for a Smartphone that will enable a user to visualize his surroundings under low light level conditions.

Other objects of the invention will in part be obvious and will in part appear hereinafter when the following detailed description is read in connection with the accompanying drawings.

### SUMMARY OF THE INVENTION

A night vision attachment for a SmartPhone by which the camera of the SmartPhone is enabled to view or take digital photos and or videos of objects under very low light ambient light levels.

The night vision attachment is adapted to be used with SmartPhones having cameras and comprises a housing for receiving and locating components of the attachment. The housing has portions adapted to mate with a wall of the camera through which the phone camera lens images object space.

Located in the attachment housing are:
an image detector located in the housing along an optical path;
an objective lens located along the optical path for forming images on the image detector whereby the image detector operates to generate image output signals representative of detected images;
a display arranged to receive the image output signals from the image detector and to generate a visible image; and
an eyepiece positioned in said housing for viewing images formed on said display and permitting the camera of the phone to focus on said display images when said attachment is mated to a phone.

Snap fit connectors depend from the housing for snapping around the camera releasably hold the attachment in mating contact with the phone so that the camera of the phone is optically aligned with the axis of the eyepiece to permit the camera to view images on said display via the eyepiece.

In an aspect of the invention, the camera and illumination system of the attachment comprises a solid state imager having an operating mode having substantial sensitivity to infrared radiation within its field of view and adapted to generate an image output signal representative of the subject matter that it observes and a radiation source to generate infrared radiation and to direct such radiation into the field of view of the solid state imager.

In another aspect of the invention, a display is arranged to receive the image output signal from the solid state imager and to generate an image visible to the SmartPhone camera via the eyepiece.

### BRIEF DESCRIPTION OF THE DRAWINGS

The structure and operation of the night vision modular system of the present invention, together with other objects and advantages thereof, may best be understood by reading the following detailed description in connection with the drawings in which unique reference numerals have been used throughout for each part and wherein:

FIG. 1A is an exploded diagrammatic perspective view of a SmartPhone and an inventive attachment separated from the SmartPhone;

FIG. 1B is a diagrammatic perspective view of the SmartPhone and attachment of FIG. 1A showing the attachment mated with the SmartPhone to convert it for use in taking digital photos and or video or allowing a user to visualize her surroundings under low ambient light level conditions;

FIG. 2A is a diagrammatic perspective of the inventive SmartPhone attachment with parts broken away to visualize aspects of its optical system;

FIG. 2B is an enlarged diagrammatic perspective of a portion of the inventive attachment shown in FIG. 2A;

FIG. 3A is a diagrammatic perspective of the inventive SmartPhone attachment with parts broken away to visualize aspects of its optical and illumination system;

FIG. 3B is an enlarged diagrammatic perspective of a portion of the inventive attachment shown in FIG. 3A;

FIG. 4 is a schematic block diagram view of the optical and image-generating components of the inventive SmartPhone attachment shown in FIGS. 1A thru 3B and illustrate the camera and display module used in conjunction with an auxiliary optical module; and

FIG. 5 is a block diagram showing the generation and display of image signals from components of the inventive modules; and

FIG. 6 is a graph showing a typical spectral response of the solid state imager and a typical spectra of the emissions from the light emitting diodes shown in FIG. 4 and elsewhere.

### DETAILED DESCRIPTION OF THE INVENTION

The present invention is an attachment for a SmartPhone, or the like, by which the camera of the SmartPhone can be used to take digital photos and or videos, or its user can visualize his surroundings, under very low ambient light levels. Under low light level conditions beneath which the SmartPhone cannot “see” its surroundings, the attachment operates to provide images to the SmartPhone's camera at light levels that the SmartPhone camera can see and which, in turn, enables the SmartPhone camera to operate normally as though the light levels were higher.

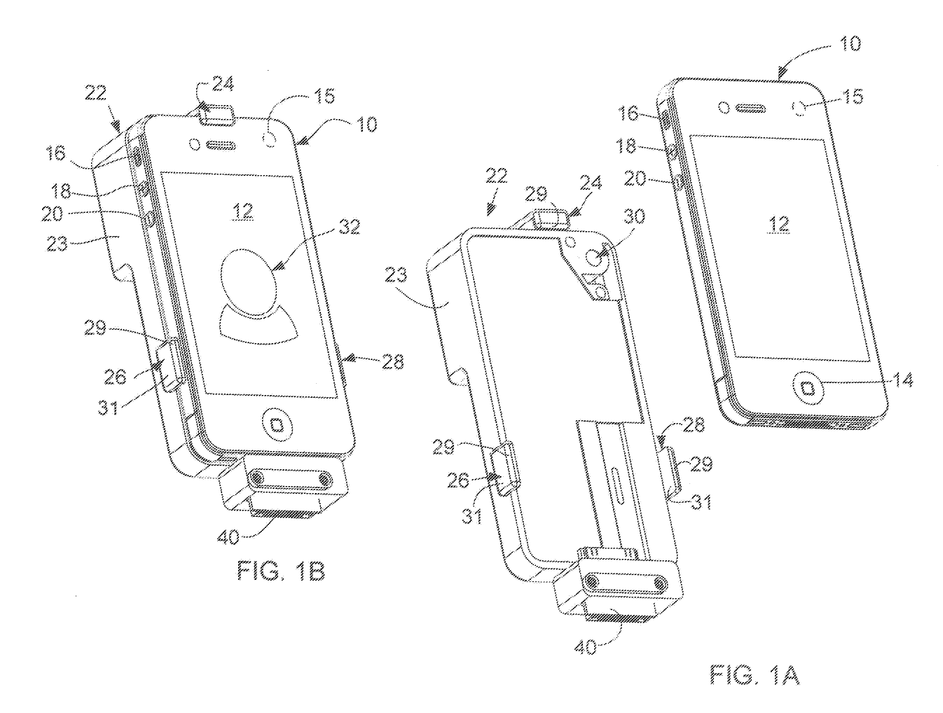

To understand how the inventive attachment achieves its purpose, reference is now made to FIG. 1A which is a diagrammatic view showing in perspective a SmartPhone 10 separated from an inventive attachment 22.

SmartPhone 10 may be any of a number of those marketed in large volumes such as the Apple i-phone series or Samsung Galaxy series, or the like. It is well-known that such phones have optical systems that may acquire images of their surroundings and present them for viewing on high resolution touch and display screens such as that designated generally at 12. Such optical systems, designated generally at 15, typically face a scene to be visualized and reside on the side opposite their display screen 12. Other controls such as those designated generally at 14, 16, 18 and 20 are utilized in a well-known manner to select and control other features including, but not limited to, gaining access to the internet, interacting with resident apps, listening to audio files, looking at video files, or the like.

Referring now to FIG. 18, the low light level attachment 22 can be seen to have housing 23 that is provided with a shape that is designed to mate in complementary fashion with the back side of the SmartPhone 10 where it is held in place against the back side via three flexible fingers 24, 26 and 28. The flexible fingers 24, 26 and 28 are cantilevered from the attachment 22 via a camming section 29 and flexible cantilevered section 31 that bends under the influence of the camming action of camming section 29 pressed against the edges of the backside of SmartPhone 10. Housing 23 otherwise is configured in a well-known manner to receive and position various components of attachment 22 to be described in more detail hereinafter.

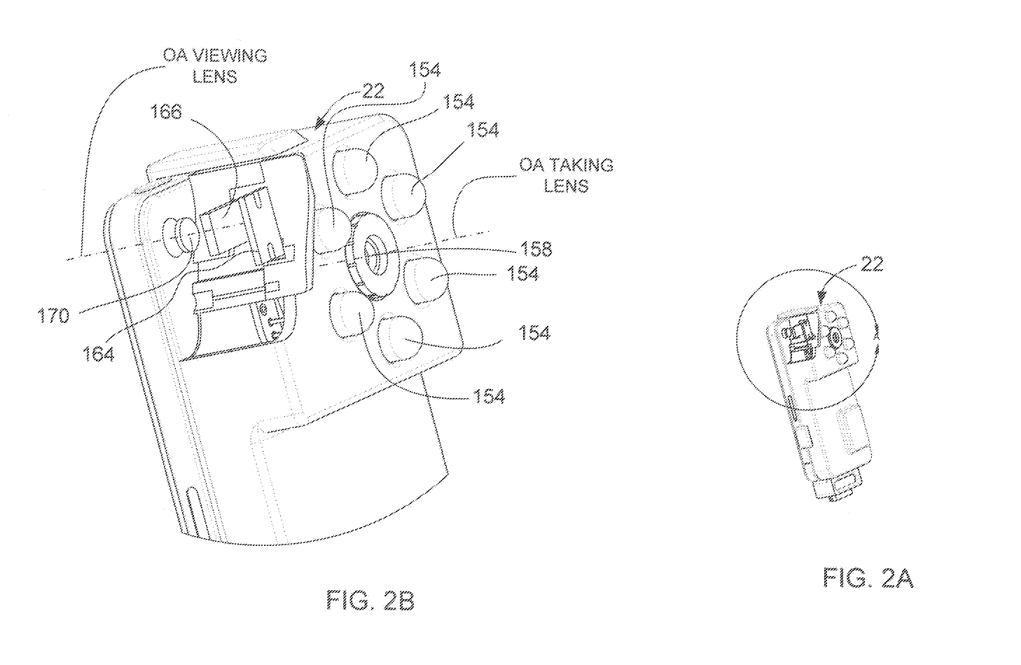

As best shown in FIG. 1A, attachment 22 is provided with an aperture 30 that is positioned so that it is automatically aligned with the optical system of SmartPhone 10 when attachment 22 is mated with the SmartPhone 10 as shown in FIG. 1B. Aperture 30 permits the optical system of SmartPhone 10 to view an image formed on a display (See display 166 in FIG. 2B) that forms part of attachment 22's optical and illumination system to be described more fully later. As depicted in FIG. 1B, attachment 22 operates under very low ambient lighting conditions to provide images on screen 12, such at that designated at 32, that SmartPhone 10 would otherwise not be able to provide.

Attachment 22 is powered either by the internal battery of SmartPhone 10 via a well-known connector 40 into which SmartPhone 10 plugs or by a separate power pack that plugs into the free end of connector 40, i.e. the end that is not occupied by SmartPhone 10.

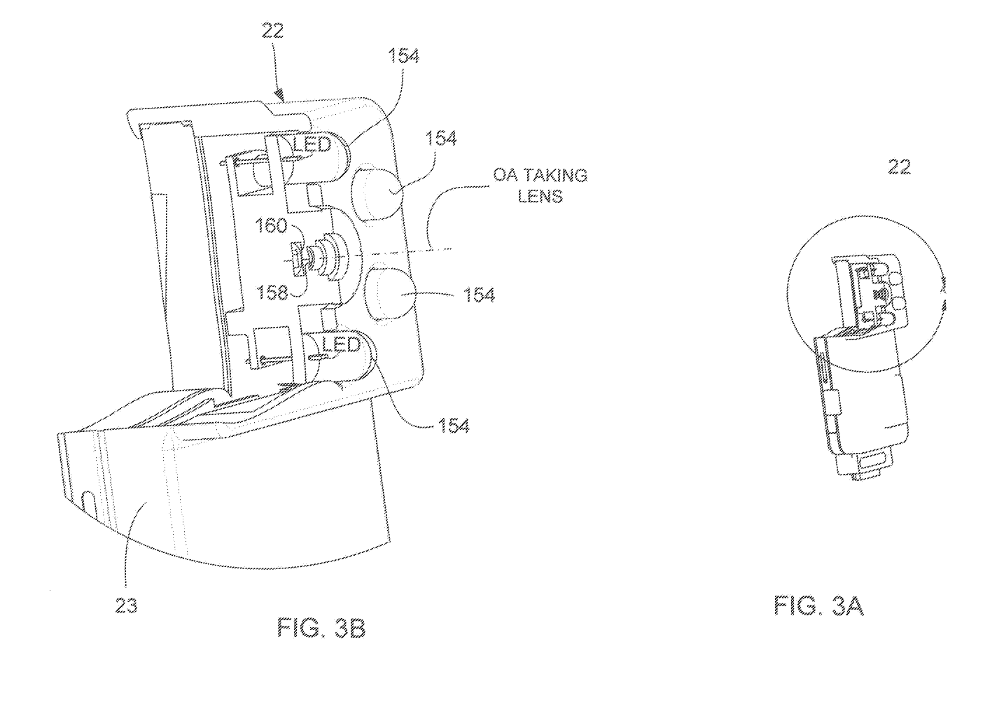

Referring now to FIGS. 2A through 3B, the manner by which attachment 22 forms images on display 166 under low light level conditions will now be taken up. Generally, it involves the use of a solid state imager 160 sensitive to infrared radiation, a source for generating infrared radiation (a series of encapsulated IR LEDs 154) within the spectral response range of the solid state imager 160 and directing this radiation into the field of view of the imager 160, and an image generator 166 that receives the output from the imager 160 and generates a visible image representative of the output of the image at a position visible to SmartPhone 10's camera as seen through aperture 30. Thus, in contrast to passive military night vision apparatus, the night vision attachment of the present invention is an “active” apparatus which generates infrared radiation used to form the image. Since the scene being viewed is being “illuminated” (in the infrared) by the attachment itself, the attachment of the present invention can use a solid state imager much less sensitive, and much less costly, than the image intensifier tube arrangements typically used in military night vision apparatus. The preferred form of solid state imager for use in the present invention is a complementary metal oxide semiconductors (CMOS) device, although other solid state imagers may also be used.

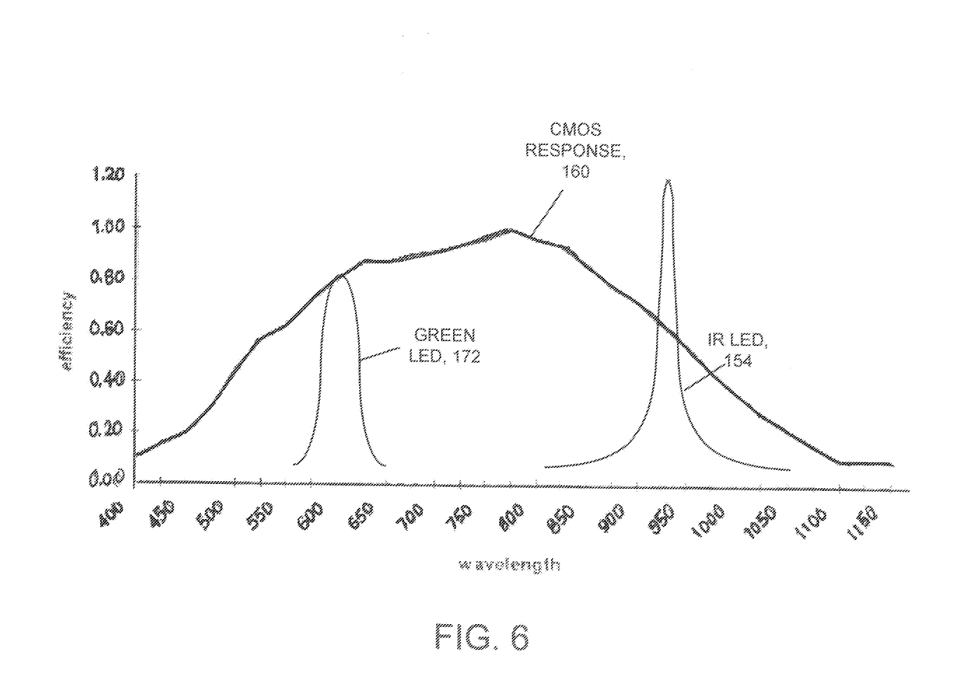

As discussed in more detail below with regard to FIG. 6, CMOS imagers are usually sensitive to infrared radiation only in the range of about 700 to 1000 (or in some case at wavelengths as long as 1050-1075) nm. CMOS sensors are, of course, also generally sensitive to visible radiation of 400 to 700 nm, and in the present invention, there is no particular reason to exclude visible light from the imager 160, i.e., the imager 160 can be allowed to form an image using both the infrared radiation reflected from the scene viewed and any available ambient visible light. If a CMOS sensor is used in the present invention, the infrared radiation source is chosen to generate infrared radiation within the range of about 700 to 1000 nm to which such imagers are particularly sensitive. Also, it is desireable to illuminate the scene at wavelengths that will not be visible to the user of the device or an individual in the vicinity of the device. Fortunately, inexpensive infrared radiation emitting diodes operating within this range are readily available commercially. Operating in the 700 to 1000 nm range also has the advantage that the images generated using such near infrared radiation are much more similar to visible images than images formed using far infrared radiation with wavelengths of 2000 nm or more, and hence are easier for inexperienced users to interpret.

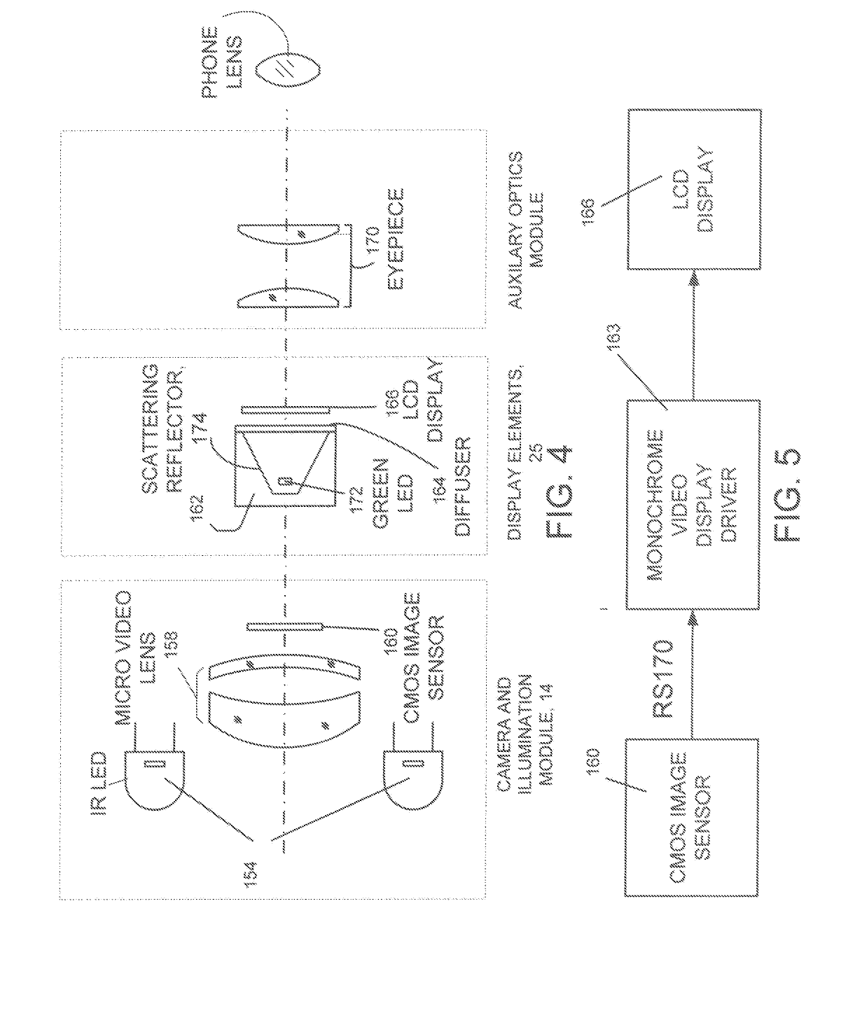

As best seen in FIGS. 2A and B, attachment 22 has an objective lens 158 arranged along optical axis. Objective lens 158 may be an aspherized singlet to bring it to an acceptable state of correction or may be of more complex design including more than one element any or all of which may include aspheric surfaces (See FIG. 4). Objective lens 158 is preferably fixed focus set to a hyperfocal distance of may be focused at or near infinity. As may be noted, the optical axis of objective lens 158 is offset with respect to the optical axis of display 166 which in turn is in axial alignment with the taking lens of SmartPhone 10. As such there is some degree of parallax between what the SmartPhone 10 would see without attachment 22 and what it sees with the attachment in place but this is negligible and is not noticeable to a user since the user observes images formed by the attachment on screen 12.

Surrounding the optical axis of objective lens 158 are a plurality of IR LEDs 154 which may all be turned on at once to optimize the distance at which images may be formed.

The camera and illumination system of attachment 22, as best seen in FIGS. 4 and 5, comprises the objective taking lens 158, preferably a centrally located micro video lens, surrounded by the circular pattern of IR LEDs 154. Behind the micro video lens 158 is located a CMOS image sensor 160 (See FIGS. 3B and 3).
The LEDs 154 used are preferably of two different types, one having a narrow field of emission and the other having a substantially wider field of emission, with the two types alternating around the circular pattern. It has been found that this arrangement of narrow angle and wide angle diodes provides optimal illumination of the entire field of view of the image sensor 160, the narrow angle diodes illuminating more distant objects while the wide angle diodes the closer objects. However, it will be recognized that one or the other can be used or used in different geometries and quantities consistent with the need to minimize the power consumption of attachment 22 and hence the drain on batteries.

A red filter may be mounted forward of the LEDs 154 to pass infrared and visible radiation having wavelengths greater than about 650 nm.

The other optical and image-forming components are as follows (Refer to FIG. 4):

(a) the micro video lens 158 which extends through a central aperture along the optical axis, gathers infrared and visible radiation, and images this radiation on to

(b) the CMOS sensor 160 mounted along the optical axis in the camera and illumination module 14;

(c) a display elements 25 comprising a back-lighting unit 162 having the form of a green light-emitting diode (see below with reference to FIG. 6) combined with a scattering reflector 174. In FIG. 2B, the scattering reflector 174 and diffuser 164 have been omitted for ease in seeing LCD display 166;

(d) a diffuser 164 disposed adjacent the back-lighting unit 162 to diffuse light emitted from the back-lighting unit;

(e) a liquid crystal display 166 disposed adjacent the diffuse 64 so as to be backlit by light passing therethrough;
(f) an auxiliary optics module comprising an eyepiece assembly 170 arranged to form provide an image of the display 166 at a distance that can be focused on by the camera lens of SmartPhone 10. Those skilled in the art of optical design will readily be able to adjust the properties of eyepiece 170 to accommodate the SmartPhone's camera lens.

The mode of operation of the optical and imaging components 158-170 of the invention will now be explained with reference to FIGS. 4 and 5. As shown schematically in FIG. 4, the infrared LEDs 154 emit infrared radiation that passes through a filter (not shown), is reflected from objects in front of the user, passes back through a centrally located aperture, and is imaged by the two-element micro video lens 158 on the CMOS sensor 160. As shown in FIG. 5, the sensor 160 generates a standard RS170 video output signal that is fed to a monochrome video display driver 163. The output from driver 163 is fed to the liquid crystal display 166.

Returning to FIG. 4, it will be seen that the back-lighting unit 162 comprises a green LED 172 lying within a frusto-conical cavity in a scattering reflector 174, the diffuser 164 lying across the wide end of the frusto-conical cavity. A green diode is chosen because this is the color to which the human eye is most sensitive, and hence minimizes light output and power consumption for an image of any desired intensity. Also, it is reminiscent of the color of phosphors used in some military night vision systems and provides a desirable user comparison to traditional military night vision systems. The combination of the scattering reflector 174 and the diffuser 164 provides a substantially uniform distribution of green light across the diffuser 164 and hence substantially uniform back-lighting of the display 166 disposed adjacent the diffuser 164. Green light passing through the display 166 is imaged by the two-element eyepiece assembly 170 of the auxiliary optics module to form an image visible to the SmartPhone camera.

The arrangement of optical and imaging components shown in FIGS. 4 and 5, in which the sensor 160 and the display 166 are substantially aligned along a common axis, provides an extremely compact and convenient form factor. The arrangement is also designed to avoid two potential problems. As shown in FIG. 6, the infrared diodes 154 emit at around 850 nm, the green diode 172 emits around 575 nm, and the sensor 160 has substantial sensitivity over the range of about 475 to about 1075 nm. Accordingly, it is necessary to arrange the optical system so that no light from green diode 172 can reach the sensor 160, since the sensor would be affected by the green light and the desired infrared image would be degraded. The arrangement of the green diode 172 within the frusto-conical cavity of the reflector 174 and the mounting of the sensor 160 immediately adjacent the “back” surface of the reflector 174 (i.e., the surface facing away from the diffuser 164) prevent light from the green diode 172 reaching the sensor 160. Also, for reasons already noted, it is undesirable for a night vision system to emit any visible light, and proper filtering assures that any light from the green diode 172, which may be reflected forwardly (i.e., away from the user), for example by reflection from the display 166, will not emerge from this module.

The preferred attachment of the present invention shown in the accompanying drawings is simple, compact and can readily be manufactured using inexpensive, commercially available components. For example, the monochrome display driver can be a Motorola MCVVQ111 VirtuoVue driver, while the display 166 can be a Cyberdisplay 320 display, available from Kopin Corporation of Taunton Mass., with a 320×240 pixel output. The sensor 160 can be an OmniVision OV5116N CMOS sensor available from OmniVision Technologies, Inc., of Sunnyvale Calif., while the infrared diodes 154 can be Model RT-7507ET from Rodan (Taiwan) Ltd., and the green diode 174 can be a Kingbright Model AA3528 surface mount LED lamp. Using such components, bright images within the range from about 30 to 100 feet can be readily seen.

It will readily be apparent to those skilled in the art that numerous changes and modifications can be made to the preferred embodiments of the invention described above without departing from the scope of the invention. For example, the CMOS sensor 160 could be replaced by another type of solid state imager, for example a charged coupled device (CCD). A color camera that also has extended infrared sensitivity could be used in conjunction with a color display to provide a color rendition of the visible scene. Higher resolution (high-definition) imager and displays could be used with associated higher costs. Therefore, it is intended that the embodiments described herein be considered as illustrative and not be construed in a limiting sense. From the foregoing, it will be seen that the present invention provides a night vision apparatus that is adaptable, inexpensive, compact, robust and well suited for use by the general public, and which does not emit visible radiation permitting observations that can be made at night without notice by or disturbing animals.

If there is sufficient light, there may be no need for the illumination module to be activated to supply additional illumination to the scene. If a visible light detector is incorporated into the illumination system or if the camera is used (with the illumination system turned off) to measure the amount of ambient light, a determination can he made as to whether additional illumination is required and the output of the illumination source adjusted to add additional illumination. If additional illumination is required to view the scene, either infrared light and/or visible light can be activated. The advantage of using infrared light is that it will not be observed by individuals or animals that are in the immediate area of the illumination system.

Other embodiments of the invention will be apparent from its teachings, and such variants are intended to be within the scope of the appended claims.

What is claimed is:

1. An night vision attachment for a phone having a camera with an optical axis, said attachment comprising:
a housing for receiving and locating components of the attachment, said housing having portions adapted to mate with a wall of the camera through which the phone camera lens images object space;
an image detector located in said housing along an optical path;
an objective lens located along said optical path for forming images on said image detector whereby said image detector generates image output signals representative of detected images;
a display arranged to receive said image output signals from said image detector and to generate a visible image;
an eyepiece positioned in said housing for viewing images formed on said display and permitting the camera of the phone to focus on said display images when said attachment is mated to a phone; and
a mechanical connector depending from said housing for snapping around the camera to releasably hold said attachment in mating contact with the phone so that the camera of the phone is optically aligned with the axis of said eyepiece to permit the camera to view images on said display via said eyepiece.

2. The night vision attachment of claim 1 wherein said image detector comprises a solid state imager having an operating mode having substantial sensitivity to infrared radiation, said solid state imager having a field of view; and wherein said night vision attachment further includes a radiation source to generate infrared radiation and to direct such radiation into said field of view of said solid state imager.

3. The night vision attachment of claim 2 wherein said solid state imager is a complementary metal oxide semiconductor device.

4. The night vision attachment of claim 2 wherein said solid state imager is sensitive to infrared radiation in the range of about 700 to about 1000 nm.

5. The night vision attachment of claim 4 wherein said solid state imager is also sensitive to visible radiation in the range of about 400 to about 700 nm.

6. The night vision attachment of claim 2 wherein said infrared radiation source comprises at least one infrared radiation emitting diode.

7. The night vision attachment of claim 6 wherein said infrared radiation source comprises at least two infrared light emitting diodes, at least one of said diodes being arranged to illuminate a wide area of said field of view of the solid state imager and at least one of said diodes being arranged to illuminate a narrower area adjacent the center of said field of view.

8. The night vision attachment of claim 2 wherein said infrared radiation source comprises at least three radiation emitting diodes arranged on a circle surrounding said lens.

9. The night vision attachment of claim 1 wherein said display comprises a backlit liquid crystal display.

10. The night vision attachment of claim 9 wherein said liquid crystal display is mounted between said solid state imager and said eyepiece so that the backlight of said liquid crystal display is not visible except via said eyepiece.

11. The night vision attachment of claim 10 wherein the backlight of said liquid crystal display is provided by a visible light emitting diode and a diffuser is provided to diffuse the light from said diode across said liquid crystal display.

12. The night vision attachment of claim 11 wherein said light emitting diode emits green light.
